(19) United States
(12) Patent Application Publication
(10) Pub. No.: US 2024/0254990 A1
(43) Pub. Date: Aug. 1, 2024

(54) SEALING ARRANGEMENT FOR A DEVICE FOR DRIVING A COMPRESSOR

(71) Applicant: Hanon Systems, Daejeon (KR)

(72) Inventors: Johannes Stausberg, Köln (DE); Michael Haag, Köln (DE); Jürgen Hoppen, Köln (DE)

(21) Appl. No.: 18/565,236

(22) PCT Filed: Dec. 27, 2022
(86) PCT No.: PCT/KR2022/021375

§ 371 Date: Nov. 29, 2023

(30) Foreign Application Priority Data
Jan. 25, 2022 (DE) 10 2022 101 681.1

(51) Int. Cl. F04C 27/00; F16L 5/02; H05K 5/06

(52) U.S. Cl. CPC F04C 27/008; H05K 5/069; F04C 2240/803; F16L 5/02

(57) ABSTRACT

A sealing arrangement for guiding electrical connections through a wall of a housing for a device for driving a compressor. The sealing arrangement has a connection arrangement with at least one electrically conductive connection element and a holding element, at least one connection terminal element for receiving the connection element in the direction of a longitudinal axis and at least one pressure element. The connection terminal element is enclosed respectively by the holding element and a sealing element around the whole circumference. In doing so, the sealing element is sealingly arranged in the region of a feed-through opening of the housing between the housing and the connection terminal element and respectively in the radial direction. The pressure element is formed for creating a sealing acting in the radial direction by means of a pressure force on the sealing element acting in the direction of the longitudinal axis.

### CROSS REFERENCE TO RELATED PATENT APPLICATIONS

This is a U.S. national phase patent application of PCT/KR2022/021375 filed Dec. 27, 2022 which claims the benefit of and priority to German Patent Application No. 10-2022-101-681.1, filed on Jan. 25, 2022, the entire contents of each of which are incorporated herein by reference.

### TECHNICAL FIELD

The invention relates to a sealing arrangement for guiding electrical connections through a wall of a housing for a device for driving a compressor, in particular an electric motor, for compressing a vaporous fluid, specifically a refrigerant. The compressor can be employed in the refrigerant circuit of an air-conditioning system of a motor vehicle.

### BACKGROUND ART

Compressors for mobile applications known from the state of the art, in particular for air-conditioning systems of motor vehicles, for transporting refrigerant through a refrigerant circuit, also referred to as a refrigerant compressor, are often formed as piston compressors with variable stroke volume or as scroll compressors, irrespective of the refrigerant. In doing so, the compressors are driven either via a pulley or electrically.

Apart from the electric motor for driving the respective compression mechanism, an electrically driven compressor has an inverter for driving the electric motor. The inverter serves to convert direct current of a vehicle battery to alternating current which is supplied to the electric motor through electrical connections.

Conventional electric motors of the electrically driven compressors can be formed with a ring-shaped stator core with coils arranged thereon and a rotor, wherein the rotor is arranged within the stator core. The rotor and the stator are oriented on a common axis of symmetry or axis of rotation of the rotor.

The inverter has plug terminals for plug connectors formed as pins for the electrical connection to terminals of the electric motor, which, on the other hand, are electrically connected to terminal lines of lead wires of the coils of the stator, also referred to as phase conductor. The terminals of the electric motor are formed in a plug housing which is, for example, arranged on an end face of the stator oriented in the axial direction of the stator.

During assembly of the compressor, the plug connectors formed as pins are respectively plugged into a connection terminal provided in the plug housing and are respectively contacted with an end piece connected to a corresponding lead wire, in particular a terminal line of the lead wire. In doing so, the end piece is electrically and mechanically connected to the terminal line of the lead wire so that respectively only a small transition resistance between the plug connector of the inverter and the lead wire is guaranteed.

The plug housing is to be electrically insulated and to be hermetically sealed against the plug connectors protruding from the motor housing and oriented to the inverter arranged outside the motor housing in order to guarantee that no fluid flowing in the compressor, specifically refrigerant and/or oil, gets into the environment and that no short circuits or damages occur in the inverter, in particular on electrical components arranged on a board of the inverter, which lead to the failure of the compressor. In doing so, in particular the mechanical part of the compressor which is charged with liquid refrigerant or oil with the electric motor and the compression mechanism driven by the electric motor is to be sealed against the inverter as an electric part of the compressor.

In order to fulfil the required insulation resistances of the electrical components and to reliably and completely insulate the current-conducting elements against fluids flowing in the motor housing and occurring pollutions, conventionally glass-metal feed-throughs of the plug connectors are employed, where the current-conducting elements are sealed with elastic shape parts. Metal seals coated with acrylonitrile-butadiene rubber, shortly also referred to as NBR (“Nitrile Butadiene Rubber”), can be used as elastic shape parts. The glass serving as insulation material and holder of the respective plug connector has a certain shape due to specified dimensions and required electrical parameters.

The shape of glass protrusions, also referred to as glass hoists, of the glass-metal feed-throughs is difficult to adjust and to reproduce and is subject to very large production-related deviations in their shape and amount. When producing the glass-metal feed-throughs, the glass in the shape of sintered hollow cylinders is introduced into a melting tool together with the pin-shaped plug connectors and holding bodies. In doing so, the tolerances of all components to be connected add up. In order to reach the desired glass shape and guarantee reliability, a plurality of very time-consuming experiments with different amounts of glass and production parameters is to be carried out. Furthermore, the proof of reliable adherence to the required limits is to be made with complex tests and proofs of capability. In order to cover or seal the glass surfaces, a respective sleeve with a tailored surface is required. In doing so, the large deviations on the part of the sealings are to be balanced both with high flexibility and with high accuracy. In particular the requirement of high accuracy is very difficult to guarantee with elastomer shape parts as sealing elements.

Furthermore, for an electrically driven compressor with an input voltage of at least 48 V, the diameter of the pin-shaped plug connectors is to be enlarged due to the higher flowing electrical current compared to a compressor with an input voltage of 470 V. Pouring the larger pin-shaped plug connectors into the glass-metal feed-throughs is very expensive. In order to guarantee a good sealing between a plug connector and the motor housing, a respective O ring sealing element could alternatively be used, whose installation, however, during the assembly is very complicated. Furthermore, an O ring sealing element is to be provided for each plug connector.

DE 11 2015 001 426 T5 reveals an electrically driven compressor with a compressor arrangement, an electric motor for driving the sealing arrangement and an inverter for supplying the electric motor with current. The electric motor has a rotor and a stator with an electrically insulating coil body arranged on an end of a stator core, coils arranged on the coil body and a plug housing with connection terminals for the electrical connection of the coils to the inverter. On the coil body, the end face of the plug housing is mechanically connected to the stator. Plug connectors are guided through a plate-shaped holding element in a hermetically sealing manner. A hermetic sealing is arranged between the holding element and a separating wall of the motor housing facing the inverter.

### SUMMARY

The object of the invention is the provision of a sealing arrangement for a device for driving an electrically driven compressor of a vaporous fluid, in particular an electric motor, which can be produced in a simple manner and assembled in a time-saving manner. The arrangement should have a number of individual components which is as small as possible and be easy to realize structurally, also in order to minimize costs during production. In doing so, the complexity of the structure of the sealing arrangement and thus the device should be minimized, wherein at the same time the sealing of the hermetic system against the environment and the electrical insulation in the interior of the compressor are optimized.

The object is achieved by the subject matter with the features as shown and described herein.

The object is achieved by a sealing arrangement according to the invention for guiding electrical connections through a wall of a housing for a device for driving a compressor. The sealing arrangement has a connection arrangement with at least one electrically conductive connection element and a holding element.

According to the concept of the invention, the sealing arrangement is formed with at least one connection terminal element for receiving the connection element in the direction of a longitudinal axis. The connection terminal element is enclosed by the holding element and a sealing element respectively in the radial direction around the whole circumference. In doing so, the sealing element, in the region of a feed-through opening of the housing between the housing, in particular the wall of the housing, and the connection terminal element, and respectively sealing in the radial direction, is arranged resting against the housing and the connection terminal element in a fluid-tight manner.

According to the invention, the sealing arrangement further has at least one pressure element for creating a sealing acting in the radial direction by means of a pressure force on the sealing element acting in the direction of the longitudinal axis.

Consequently, the sealing arrangement is specifically formed with a two-component structure of a sealing element and a pressure element.

According to a further development of the invention, the connection terminal element is arranged within a through opening formed in the holding element preferably having the shape of a plate with oppositely arranged surfaces. The through opening serves the receipt of the connection terminal element. In doing so, the holding element advantageously rests against the outside of the housing, while the connection terminal element protrudes through the feed-through opening of the housing into a volume enclosed by the housing.

Preferably an end face of the connection terminal element is arranged flush with a surface of a side of the holding element oriented facing away from the housing.

According to an advantageous design of the invention, the holding element has, on a side facing the housing, a receptacle for the sealing element which is formed around the through opening around the whole circumference and in the shape of a protrusion. The receptacle protrudes evenly, in particular with a constant extension in the radial direction, from the surface of the holding element. On the side oriented facing the housing and thus on the free end face of the receptacle, preferably an elevation is formed which is rectangular in cross-section.

A further advantage of the invention is that the sealing element is formed in a ring-shaped manner around the longitudinal axis.

The sealing element preferably has an incision formed around the whole circumference in the shape of a notch, in particular with a groove which is V shaped in cross-section, at an end face which is oriented in the axial direction. In doing so, the sealing element is preferably formed with at least two sealing lips oriented in the axial direction, which are arranged at a first end face running around the sealing element and concentrically to one another. The sealing lips are separated from one another by the incision and can be formed tapering in free end sections facing the axial direction.

In doing so, advantageously a first sealing surface is provided on a lateral surface of an inner, first sealing lip facing inside in the radial direction, while a second sealing surface is formed on a lateral surface of an outer, second sealing lip facing outside in the radial direction. Preferably, the first sealing surface of the sealing element sealingly rests against the connection terminal element and the second sealing surface in the region of the feed-through opening sealingly rests against the housing.

The sealing element preferably has a formation running around the whole circumference on a second end face oriented in the axial direction distally to the first end face. The formation is advantageously formed in the shape of a crease which is rectangular in cross-section, whose shape and dimension corresponds to the receptacle of the holding element.

The sealing element can be formed from an elastomer in order to guarantee a respective sealing connection on the sealing surfaces.

According to a preferred design of the invention, the pressure element is substantially formed in the shape of a hollow cylinder with a wall tapering on the free end face facing the sealing element in the axial direction and thus being wedge-shaped. In doing so, the wall of the pressure element preferably protrudes into the incision formed in the sealing element. The cross-section of the incision of the sealing element and the wall of the pressure element are then formed corresponding to one another.

The pressure element can be formed with sections with different inner diameters arranged along the longitudinal axis. In doing so, the pressure element preferably has at least two sections with different inner diameters and a transition which is step-shaped on the inside.

According to a further advantageous design of the invention, the connection terminal element is formed substantially in the shape of an annular cylinder with sections with different outer diameters arranged along the longitudinal axis.

The connection terminal element is preferably formed with an opening shaped as an annular cylinder extending starting from an end face facing in the direction of the outside of the housing and in the longitudinal direction of the connection terminal element, in particular a blind hole, for receiving the connection element.

A first section of the connection terminal element is preferably arranged within the through opening formed in the holding element. In doing so, the first section of the connection terminal element advantageously has an outer diameter which corresponds to an inner diameter of the through opening with a clearance. The clearance fit secures the connection terminal element in the radial direction.

The connection terminal element in particular has a second section joining the first section in the direction of the longitudinal axis which is formed with a larger outer diameter than the first section. The second section of the connection terminal element can be enclosed by the sealing element around the whole circumference at least in regions. In doing so, the second section of the connection terminal element advantageously has an outer diameter which corresponds to an inner diameter of the sealing element with a clearance.

The connection terminal element is furthermore preferably formed with a third section joining the second section in the direction of the longitudinal axis which has a smaller outer diameter than the second section so that a step-shaped transition is provided between the second section and the third section.

The connection terminal element can also have a fourth section joining the third section in the direction of the longitudinal axis which is formed with a smaller outer diameter than the third section so that a step-shaped transition is provided between the third section and the fourth section as well. The fourth section of the connection terminal element is preferably enclosed by a lead wire of a coil of a stator of an electric motor around the whole circumference so that the connection terminal element and the lead wire are in mutual electrical contact.

A further advantage of the invention is that the third section and a region of the second section of the connection terminal element joining the third section are enclosed by the pressure element around the whole circumference. In doing so, the pressure element is movable relative to the connection terminal element, in particular in the longitudinal direction and in the circumferential direction. A first section of the pressure element is preferably arranged in the region of the second section of the connection terminal element and a second section thereof is arranged in the region of the third section of the connection terminal element.

According to a further preferred design of the invention, the connection element is formed as a pin-shaped plug connector in the shape of a cylinder and preferably has the shape of a straight pin. The connection element is in particular formed in the shape of an annular cylinder with a constant outer diameter.

The connection element is preferably, with a first end ahead, inserted in, in particular screwed in, the opening formed as a blind hole at the end face of the connection terminal element facing the outside of the housing. Due to screwing the connection element through a printed circuit board into the opening of the connection terminal element, the connection terminal element can be fixed in the axial direction.

The connection element with the connection terminal element preferably serves to connect electrical terminals arranged inside the housing, in particular the lead wire of the coil of the stator of the electric motor, to electrical terminals arranged outside the housing, in particular an inverter. In doing so, an end face of the connection terminal element can be electrically connected to a conductor path formed on the printed circuit board of the inverter. Alternatively, the connection element can be plated-through with the conductor path of the printed circuit board.

A method for assembling a sealing arrangement for guiding electrical connections through a wall of a housing has the following steps:
connecting at least one connection terminal element to a holding element through guiding the connection terminal element into a through opening formed in the holding element in the direction of a longitudinal axis,
sliding a sealing element onto the connection terminal element in the direction of the holding element and placing the sealing element on the holding element,
sliding a pressure element in the direction of the longitudinal axis onto the connection terminal element in the direction of the holding element with the sealing element and placing the pressure element on the sealing element,
introducing the connection terminal element into a feed-through opening formed in a wall of the housing in the direction of the longitudinal axis, wherein the sealing element is arranged between the housing and the connection terminal element,
connecting a lead wire as a terminal line of a coil in the region of an end face of the connection terminal element to the connection terminal element, and
fixing the holding element on the housing, wherein the pressure element is pressed onto the sealing element arranged on the holding element in the direction of the longitudinal axis so that the sealing element is deformed in the direction of the longitudinal axis and in the radial direction and seals in the radial direction.

When pressing the pressure element against the sealing element, a wall of the pressure element can be pushed into an incision formed in the sealing element in the direction of the longitudinal axis. In doing so, sealing lips formed on the sealing element are pushed apart in the radial direction and the sealing element with sealing surfaces is pushed against the housing and the connection terminal element.

Furthermore, a connection element can be introduced into an opening formed in the connection terminal element in the longitudinal direction, in particular screwed in, so that the connection element and the connection terminal element are oriented coaxially to one another and electrically connected to one another.

A device for driving a compressor of a vaporous fluid, in particular an electric motor, has a rotor and the immobile stator, which extend along a common longitudinal axis, and the housing. The stator is advantageously positioned in the radial direction on an outside of the rotor, enclosing the rotor.

The sealing arrangement according to the invention is formed on a first end face of the stator oriented in an axial direction.

In this case, the axial direction is understood to be the direction of the longitudinal axis of the stator which also corresponds to the longitudinal axis and the axis of rotation of the rotor. An end face oriented in the axial direction is arranged in a plane oriented perpendicular to the longitudinal axis.

The advantageous design enables the use of the device for driving a compressor, in particular an electric motor, for compressing a vaporous fluid for a compressor of a refrigerant in a refrigerant circuit of an air-conditioning system of a motor vehicle.

The sealing arrangement according to the invention or the device for driving a compressor of a vaporous fluid with the sealing arrangement have, in summary, further various advantages:
minimum number of components, as separate sealing elements, for example, such as a metal sealing, are omitted compared to the arrangements of the state of the art,
simple and time-saving assembly of components with low complexity, thus reduction of assembly steps and minimum production and assembly costs, and
maximum functional safety through radial sealing.

### DESCRIPTION OF DRAWINGS

Further details, features and advantages of designs of the invention result from the following description of example embodiments with reference to the accompanying drawings. The following is shown:

FIG. 1A: an electrically driven compressor with a device, in particular an electric motor, for driving a compression mechanism and an arrangement of an inverter in a sectional view,

FIG. 1B: a stator of the electric motor with a stator core, coils, an insulation and a support element in a perspective view,

FIG. 2A: a connection arrangement of a sealing arrangement for connection elements with a holding element and shape elements for the electrical connection of terminals arranged in the plug housing to terminals of the inverter of the state of the art in a perspective view,

FIG. 2B: a detail of a sealing arrangement with the connection arrangement of FIG. 2A with a sealing element of the state of the art in a sectional view,

FIG. 2C: a detail view of the sealing arrangement, in particular the sealing element, of FIG. 2B,

FIGS. 3A to 3C: a sealing arrangement according to the invention for guiding electrical connections through a housing of a device for driving a compressor in different detailed sectional views,

FIG. 4A: a holding element with sealing elements of the sealing arrangement of FIGS. 3A to 3C, and

FIG. 4B: a sealing element of the sealing arrangement of FIGS. 3A to 3C as a single element, and

FIG. 5: a pressure element of the sealing arrangement of FIGS. 3A to 3C as a single element.

### DESCRIPTION OF AN EMBODIMENT

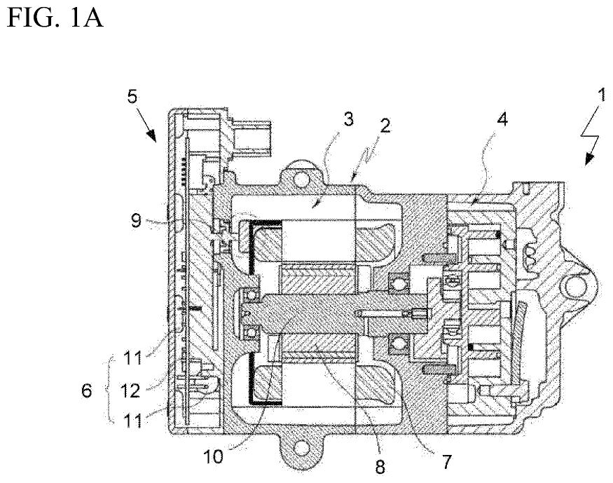

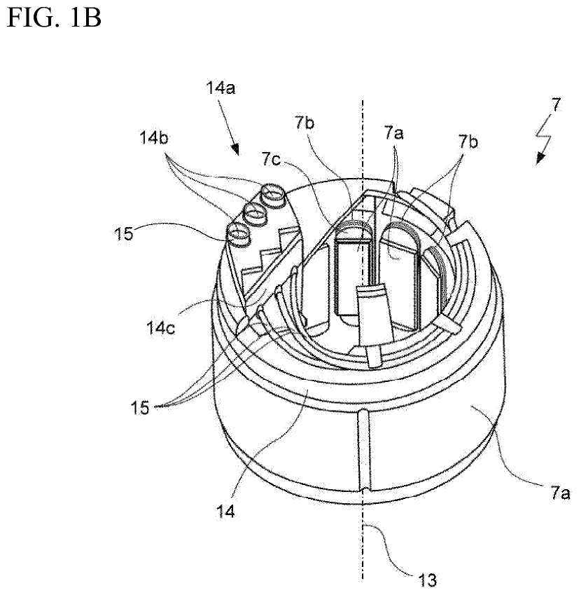

FIG. 1A reveals an electrically driven compressor 1 of a vaporous fluid, specifically for an air-conditioning system of a motor vehicle for transporting refrigerant through a refrigerant circuit, with an electric motor 3 arranged in a housing 2 as a device 3 for driving a compression mechanism 4 and an arrangement of an inverter 5 in a sectional view. The electric motor 3 is supplied with electric energy via a switch device 6 of the inverter 5.

The electric motor 3 has a stator 7 with a stator core which is substantially shaped as a hollow cylinder and coils wound onto the stator core and a rotor 8 arranged within the stator 7. The rotor 8 is put into a rotational movement when the coils of the stator 7 are supplied with electric energy via a connection arrangement 9. The connection arrangement 9 is formed on an end face of the stator 7 and has a plurality of electrical connections.

The rotor 8 is coaxially within the stator 7 and arranged rotatably about an axis of rotation. A drive shaft 10 can be formed integrally with the rotor 8 or as a separate element.

The electric motor 3 and the connection mechanism 4, which is, as an example, formed as a scroll compressor with a fixed and an orbiting spiral, are arranged within a volume enclosed by the housing 2. In doing so, the housing 2 is formed from a first housing element for receiving the electric motor 3 and a second housing element for receiving the compression mechanism 4 and preferably from a metal, in particular from an aluminum.

The orbiting spiral of the compression mechanism 4, in which the vaporous fluid, specifically a refrigerant, is compressed, is driven via the drive shaft 10 connected to the rotor 8 of the electric motor 3. According to a non-represented embodiment, the compression mechanism can, for example, also be formed with a swash plate.

The switch device 6 for controlling the operation of the electric motor 3 has a printed circuit board 12 formed with different switch elements 11. On the printed circuit board 12, different drive circuits and components are assembled in an electrically connected manner and which are supplied with electric energy from an external power source.

In FIG. 1B a stator 7 of the electric motor 3 is shown in a perspective view. The stator 7 is formed with a stator core 7a, coils 7b, an insulation 7c and a support element 14 with a receiving element 14a for a plug housing 14c.

The electric motor 3, for example an alternating current motor with three phases, has the non-represented rotor and the stator core 7a arranged in the radial direction on an outside of the rotor and thus around the rotor. The stator core 7a which is preferably formed as a laminated stack, and the insulation 7c formed from an electrically insulating material respectively extend along a longitudinal axis 13 which also corresponds to the longitudinal axis of the stator 7 and the axis of rotation of the rotor, from a first end face to a second end face of the stator 7.

The coils 7b are respectively formed from a wire as an electric conductor, also referred to as lead wire 15, which is wound around a region of the stator core 7a extending to the inside in the radial direction. The non-wound ends of the lead wires 15 are guided out of the respective winding as terminal lines.

The stator core 7a, the insulation 7c and the coils 7b form the stator unit of the electric motor 3.

The support element 14 with the receiving element 14a with connection passages 14b for the plug housing 14c with connection terminals is arranged on a first end face of the stator 7. The connection terminals of the plug housing 14c respectively serve as a component of an electrical connection between the coils 7b of the electric motor 3 and the non-represented inverter 5, in particular electrically conductive, pin-shaped connection elements, which are arranged guided through the connection passages 14b of the receiving element 14a of the support element 14 and plugged into the connection terminals of the plug housing 14c.

The terminal lines of the lead wires 15 of the coils 7b and the connection terminals of the plug housing 14c arranged in the receiving element 14a are connected to one another in an electrically conducting manner.

The support element 14 with the receiving element 14a and the plug housing 14c arranged in the receiving element 14a in the assembled state of the stator 7, rests against the stator 7 in the axial direction, in particular the stator core 7a. In doing so, the receiving element 14a for the plug housing 14c is formed as a component of the support element 14. The support element 14 with the receiving element 14a with the connection passages 14b for the plug housing 14c with the connection terminals is formed as one unit, in particular as a single-piece injection-molded element. The single-piece formation is realized within a shaping process.

In order to introduce the connection elements as electrical connectors to the non-represented inverter 5 through the enclosure of the receiving element 14a and into the plug housing 14c, the connection passages 14b are provided within the enclosure of the receiving element 14a. The connection passages 14b are oriented in the axial direction.

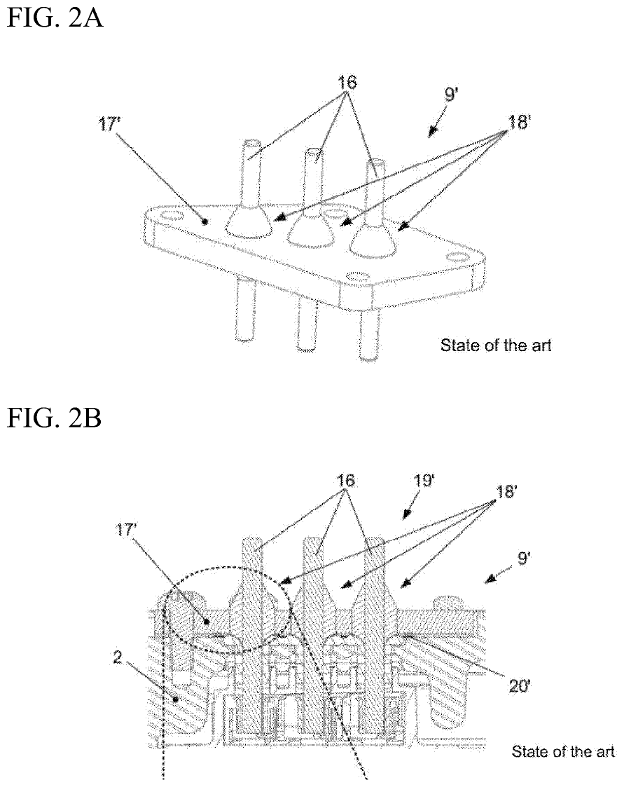

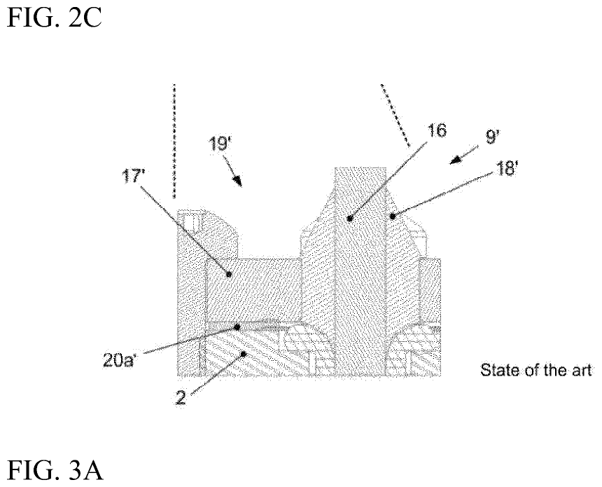

In FIG. 2A a connection arrangement 9′, in particular a glass-metal electric feed-through, of a sealing arrangement for connection elements 16 with a holding element 17′ and shape elements 18′ for the electrical connection of terminals arranged in the non-represented plug housing 14c to terminals of the inverter 5 of the state of the art, not represented either, is represented in a perspective view. FIG. 2B reveals a section of a sealing arrangement 19′ with the connection arrangement 9′ of FIG. 2A with a sealing element 20′ for sealing the holding element 17′ against the housing 2 of the state of the art in a sectional representation, while FIG. 2C shows a detailed view, in particular of the sealing element 20′ of FIG. 2B.

The connection elements 16 are arranged guided through the plate-shaped holding element 17′. Every connection element 16 having the shape of a straight pin, in the following also referred to as plug connector 16, is arranged forming three different regions which are oriented along a common axis, in particular a longitudinal axis. In doing so, a respective first region and a second region protrude from the opposing surfaces of the plate-shaped holding element 17′. A third region of the plug connector 16 is respectively arranged within the holding element 17′.

The plug connectors 16 which are preferably formed as straight annular cylinders with a diameter which is constant along the length, are respectively arranged with the third section within a through opening provided in the holding element 17′. In doing so, the inner diameter of the through opening corresponds to the outer diameter of the plug connector 16 with a clearance for assembling and fixing the plug connector 16 within the through opening. The gap formed between the plug connector 16 and the wall of the holding element 17′ running around the through opening is filled by the shape element 18′, in particular a glass shape element or a glass body. The shape element 18′ filling the gap, preferably formed from a glass, serves, on the one hand, respectively the fixing of the plug connector 16 within the through opening and thus on the holding element 17′ and, on the other hand, the insulation of the electrically conductive plug connector 16 against the holding element 17′. In doing so, the shape element 18′ protrudes from the plane of the respective surface of the holding element 17′ in the direction of the plug connector 16. The protrusions of the shape element 18′ respectively substantially have the shape of a cone or of a truncated cone.

As revealed in FIGS. 2B and 2C, a sealing element 20′ is arranged on the side of the holding element 17′ oriented to the housing 2, which seals the holding element 17′ with the plug connector 16 protruding from the holding element 17′ and shape element 18′ towards the housing 2. The sealing element 20′, which on the one hand in particular rests against a sealing seat surface of the housing 2 and on the other hand the holding element 17′, serves to hermetically seal the housing 2 and thus prevent the leakage of fluid flowing within the housing 2, specifically refrigerant and/or oil, into the environment and thus also to the non-represented inverter 5 and the electrical components arranged on the printed circuit board 12 of the inverter 5.

The sealing element 20′ is formed as an NBR-coated metal seal with a sealing bead 20a′. The sealing bead 20a′ is compressed by tightening fixation screws for connecting the holding element 17′ to the housing 2.

Different temperature loads cause strains and shrinkage of the sealing element 20′, which affect the complete component arrangement, having the housing 2, the holding element 17′ and the sealing element 20′, and can lead to a decrease of the remaining torque of the screw connections or a loosening of the fixation screws and finally to a leakage in the region of the holding element 17′.

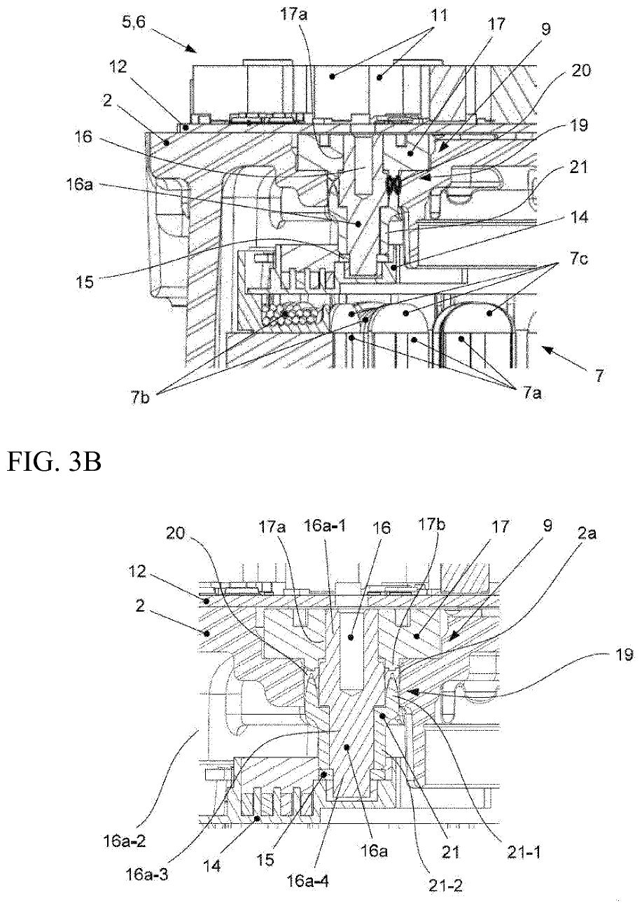

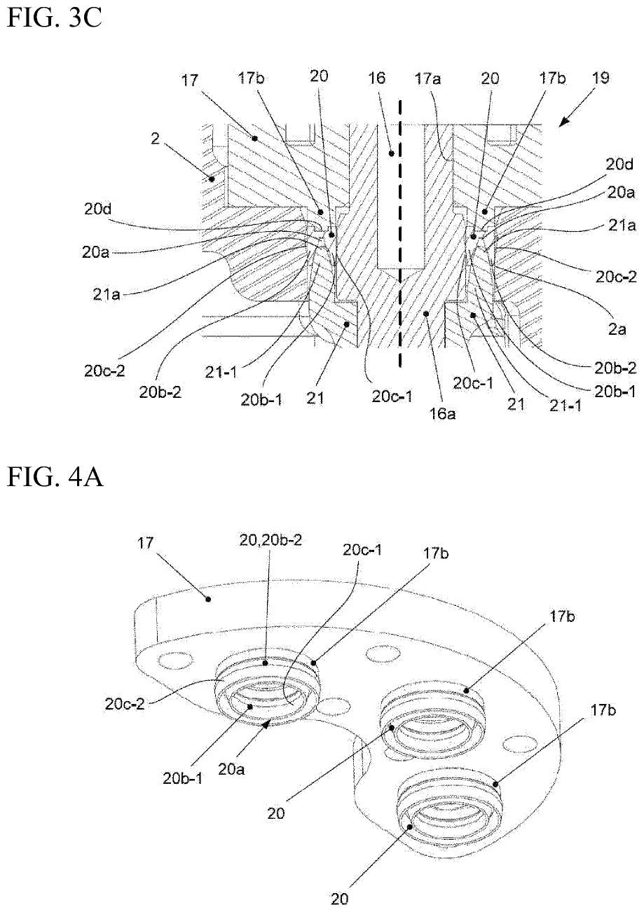

FIGS. 3A to 3C respectively reveal a sealing arrangement 19 according to the invention for guiding plug connectors 16 as electrical connection elements through the housing 2 of a compressor, specifically as a connection to the electric motor as a device for driving the compressor, in different detailed sectional representations.

Within the housing 2 having a side wall and an end face with a feed-through opening 2a for guiding the plug connector 16 through, the stator 7 of the electric motor with the stator core 7a, the coils 7b, the insulation 7c and the support element 14 is arranged.

An end of a lead wire 15 respectively wound to a coil 7b around a region of the stator coil 7a extending to the inside in the radial direction is guided out of the respective winding as a terminal line and along the support element 14 to a connection terminal element 16a. The connection terminal element 16a serves as a component of the electrical connection between the coil 7b of the electric motor 3 and the inverter 5, in particular the electrically conducting, pin-shaped plug connector 16, a first end of which is arranged guided through the feed-through opening 2a formed in the end face of the housing 2 or introduced into the feed-through opening 2a and plugged into the connection terminal element 16a.

The switch device 6 of the inverter 5 with the printed circuit board 12 and the switch elements 11 provided on the printed circuit board is fixed on the surface of the end face of the housing 2 facing the environment of the housing 2. In doing so, the printed circuit board 12 can rest against the housing 2. The plug connector 16 is plated-through with a conductor path of the printed circuit board 12 so that an electrically conducting connection to the lead wire 15 of the coil 7b of the stator 7 is created between the switch device 6 of the inverter 5 via the plug connector 16 and the connection terminal element 16a. Alternatively, the connection terminal element 16a can be electrically connected to a conductor path formed on the printed circuit board 12 on the end face facing the printed circuit board 12.

The connection terminal element 16a is arranged within a through opening 17a formed in the holding element 17. In doing so, the substantially cylinder-shaped connection terminal element 16a has regions with different outer diameters along the longitudinal axis. A first section 16a-1 is formed with an outer diameter which corresponds to an inner diameter of the through opening 17a formed in the holding element 17 with a clearance. The connection terminal element 16a is connected to the holding element 17 via a clearance fit within the through opening 17a.

A second section 16a-2 joining the first section 16a-1 in the axial direction and thus in the direction of the longitudinal axis of the connection terminal element 16a has a larger outer diameter than the first section 16a-1.

The second section 16a-2 is enclosed by a ring-shaped sealing element 20 around the whole circumference at least in regions. In doing so, the second section 16a 2 is formed with an outer diameter which corresponds to an inner diameter of the ring-shaped sealing element 20 with a clearance for sliding the sealing element 20 onto the connection terminal element 16a.

A third section 16a-3, which, on the other hand, joins the second section 16a-2 in the direction of the longitudinal axis of the connection terminal element 16a, has a smaller outer diameter than the second section 16a-2 so that a step-shaped transition is formed between the second section 16a-2 and the third section 16a-3.

The third section 16a-3 of the connection terminal element 16a and a region of the second section 16a-2 of the connection terminal element 16a joining the third section 16a-3 are enclosed by a pressure element 21 shaped substantially as hollow cylinder around the whole circumference. The third section 16a-3 of the connection terminal element 16a is formed with an outer diameter which corresponds to an inner diameter of the pressure element 21 with a clearance for sliding the pressure element 21 onto the connection terminal element 16a. In doing so, the inner diameter of the pressure element 21, in particular in the assembled state of the sealing arrangement 19 according to FIG. 3C, is larger in the region of the second section 16a-2 of the connection terminal element 16a than the outer diameter of the second section 16a-2 of the connection terminal element 16a. Consequently, the pressure element 21 is also formed with two sections 21-1, 21-2 with at least different inner diameters and thus a step-shaped transition on the inside. In the assembled state of the sealing arrangement 19, a first section 21-1 of the pressure element 21 is arranged in the region of the second section 16a-2 of the connection terminal element 16a, while a second section 21-2 of the pressure element 21 is arranged in the region of the third section 16a 3 of the connection terminal element 16a.

In the region of the second section 16a-2 of the connection terminal element 16a, the connection terminal element 16a is enclosed by the housing 2 such that an inner lateral surface of the sealing element 20 sealingly rests against an outer lateral surface of the second section 16a-2 of the connection terminal element 16a and an outer lateral surface sealingly rests against an inner surface of the feed-through opening 2a on the housing 2.

A fourth section 16a-4, which, on the other hand, joins the third section 16a-3 in the direction of the longitudinal axis of the connection terminal element 16a, has a smaller outer diameter than the third section 16a-3 so that a step-shaped transition is formed between the third section 16a-3 and the fourth section 16a-4 of the connection terminal element 16a. The fourth section 16a-4 of the connection terminal element 16a is enclosed by the lead wire 15 of the coil 7b of the stator 7 around the whole circumference. In doing so, the lead wire 15 rests against the lateral surface of the fourth section 16a-4 of the connection terminal element 16a around the whole circumference and can additionally rest against the end face of the step-shaped transition formed between the third section 16a-3 and the fourth section 16a-4. Thus, an electrical contact between the lead wire 15 and the connection terminal element 16a is created.

The connection terminal element 16a shaped substantially as an annular cylinder is formed as a round rod with an opening shaped as an annular cylinder extending in the longitudinal direction of the connection terminal element 16a starting from the first end face facing in the direction of the printed circuit board, in particular a blind hole, for receiving the plug connector 16. During the assembly of the connection arrangement 9, the plug connector 16 is introduced into the opening in the longitudinal direction, in particular screwed in, so that the plug connector 16 and the connection terminal element 16a are oriented coaxially to one another. In doing so, the plug connector 16 is formed with an outer diameter which corresponds to an inner diameter of the opening formed in the connection terminal element 16a.

The first end face of the connection terminal element 16a is arranged flush with a surface of the plate-shaped holding element 17 facing away from the housing 2.

In particular in FIG. 3C, the ring-shaped sealing element 20 is shown in such a sectional representation that the longitudinal axis of the plug connector 16 and of the connection terminal element 16a represents a main axis of symmetry of the sealing element 20. In doing so, the sealing element 20 is shown with two cross-sections which are symmetrical to one another with regard to the main axis of symmetry. The shapes of the cross-sections are identical to one another. Both cross-sections of the sealing element 20, on the other hand, respectively have an axis of symmetry which is oriented in parallel to the main axis of symmetry.

The ring-shaped sealing element 20 sealing in the radial direction has, on a first end face oriented in the axial direction, an incision 20a formed around the whole circumference in the shape of a notch or a groove which is V-shaped in cross-section so that the sealing element 20 is formed with two sealing lips 20b-1, 20b-2. The sealing lips 20b-1, 20b-2 arranged on the first end face around the ring-shaped sealing element 20 in a circumferential manner are separated from one another by the incision 20a in the region of the first end face and are shaped tapering towards the free end sections.

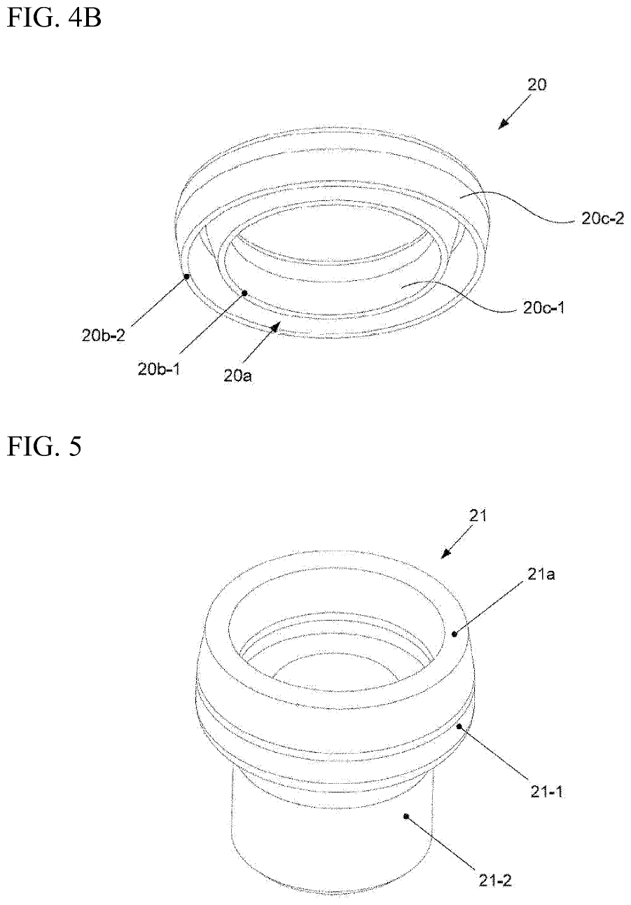

On the inner lateral surface of the inner, first sealing lip 20b-1, a first sealing surface 20c-1 facing the radial direction is formed, while on the outer lateral surface of the outer, second sealing lip 20b-2 of the ring-shaped sealing element 20, a second sealing surface 20c-2 facing the radial direction is formed, which is also revealed in FIGS. 4A and 4B. In doing so, the first sealing surface 20c 1 of the sealing element 20 formed on the inner lateral surface of the first sealing lip 20b-1 sealingly rests against the connection terminal element 16a and the second sealing surface 20c-2 formed on the outer lateral surface of the second sealing lip 20b-2 sealingly rests against the inner surface of the feed-through opening 2a of the housing 2. The sealing element 20 is thus arranged within a gap-shaped intermediate space formed between the feed-through opening 2a of the housing 2 and the connection terminal element 16a, sealing the gap.

In FIG. 4A, the holding element 17 of the connection arrangement 9 is shown with sealing elements 20 of the sealing arrangement 19, while in FIG. 4B, a sealing element 20 of the sealing arrangement 19 is represented as a single element. The sealing elements 20 are formed from an elastomer.

The sealing element 20 has, on a second end face oriented in the axial direction distally to the first end face, a formation 20d which runs around the whole circumference. The formation 20d is formed in the shape of a crease which is rectangular in cross-section.

The holding element 17 has, on the side facing the interior of the housing 2 and thus the sealing element 20, a receptacle 17b for the sealing element 20 which is formed around the whole circumference of the through opening 17a and in the shape of a protrusion. The receptacle 17b protrudes evenly from the surface of the holding element 17. Furthermore, an elevation which is rectangular in cross-section is provided on the free end face of the receptacle 17b, whose dimensions correspond to the formation 20d formed on the second end face of the sealing element 20, which is rectangular as well. Consequently, the formation 20d of the sealing element 20 is attached to the elevation of the receptacle 17b and thus connected to the holding element 17. In doing so, the end faces of the ring-shaped sealing element 20 and of the receptacle 17b of the holding element 17 lie flat against one another.

The pressure element 21, as the counterpart to the sealing element 20, is formed with a wall 21a which tapers on the free end face of the first section 21-1 facing the sealing element 20 in the axial direction, and thus is wedge-shaped, which is in particular also revealed in FIG. 5. The tapering wall 21a of the pressure element 21 is arranged protruding into the incision 20a provided in the sealing element 20. The cross-section of the incision 20a of the sealing element 20 and the tapering wall 21a of the pressure element 21 are formed corresponding to one another so that, during a progressive penetration of the pressure element 21 formed in particular of a hard plastic such as a thermoplastic or a thermosetting material, into the incision 20a in the axial direction, the sealing lips 20b-1, 20b-2 of the sealing element 20 are pressed apart in the radial direction and thus, on the one hand, against the housing 2, and on the other hand, against the connection terminal element 16a. At the same time, the sealing element 20 is pressed against the receptacle 17b of the holding element 17 so that a counter pressure on the sealing element 20 is created.

As a reaction to the pressure forces, the pressure element 20 is forced to the outside and to the inside in the radial direction in order to build up a radial pressure and thus press the sealing surfaces 20c-1, 20c-2 of the sealing element 20 against the housing 2 and the connection terminal element 16a so that the radial sealing is guaranteed.

In order to guarantee movability of the pressure element 21 with regard to the connection terminal element 16a, the pressure element 21 has, in the region of the second section 21-2, an extension which is smaller in the axial direction or a smaller length than the connection terminal element 16a in the region of the third section 16a-3. In doing so, the pressure element 21, with the free end face of the second section 21-2, which is distally opposite to the first end face with the wall 21a formed in a tapering manner, and the connection terminal element 16a with the end face formed between the third section 16a-3 and the fourth section 16a-4 at the step-shaped transition, rest against the lead wire 15, which, on the other hand, is pressed against the support element 14. The second end face of the connection terminal element 16a, which is formed distally to the first end face, protrudes into the support element 14.

With the rigid arrangement of the stator 7 with the support element 14 within the housing 2 and moving the holding element 17 in the axial direction during the fixation on the housing 2, for example by means of screw connections, the sealing element 20 arranged on the holding element 17 is also moved in the axial direction and pressed against the pressure element 21 so that the sealing effect between the housing 2 and the connection terminal element 16a is achieved.

### LIST OF REFERENCE NUMERALS

1 compressor
2 housing
2a feed-through opening of the housing 2
3 device, electric motor
4 compression mechanism
5 inverter
6 switch device
7 stator
7a stator core
7b coil
7c insulation
8 rotor
9, 9′ connection arrangement
10 drive shaft
11 switch element
12 printed circuit board
13 longitudinal axis
14 support element
14a receiving element
14b connection passage
14c plug housing
15 lead wire
16 connection element, plug connector
16a connection terminal element
16a-1 first section of the connection terminal element 16a
16a-2 second section of the connection terminal element 16a
16a-3 third section of the connection terminal element 16a
16a-4 fourth section of the connection terminal element 16a
17, 17′ holding element
17a through opening of the holding element 17
17b receptacle for the sealing element 20
18′ shape element
19, 19′ sealing arrangement
20, 20′ sealing element
20a′ sealing bead of the sealing element 20′
20a groove of the sealing element 20
20b-1 first sealing lip of the sealing element 20
20b-2 second sealing lip of the sealing element 20
20c-1 first sealing surface of the sealing element 20
20c-2 second sealing surface of the sealing element 20
20d formation of the sealing element 20
21 pressure element
21-1 first section of the pressure element 21
21-2 second section of the pressure element 21
21a wall of the pressure element 21

1-31. (canceled)

32. A sealing arrangement for guiding electrical connections through a wall of a housing for a device for driving a compressor, the sealing arrangement comprising:
a connection arrangement with at least one electrically conductive connection element;
a holding element;
at least one connection terminal element for receiving the at least one connection element formed in a direction of a longitudinal axis, which is respectively enclosed by the holding element and a sealing element around an entire circumference, wherein the sealing element is arranged in a region of a feed-through opening of the housing between the housing and the at least one connection terminal element and respectively sealing in a radial direction, resting against the housing and the at least one connection terminal element in a fluid-tight manner; and
at least one pressure element is formed for creating a sealing acting in the radial direction by means of a pressure force on the sealing element acting in the direction of the longitudinal axis.

33. The sealing arrangement according to claim 32, wherein the at least one connection terminal element is arranged within a through opening formed in the holding element, wherein the holding element rests against an outside of the housing and the at least one connection terminal element protrudes through the feed-through opening of the housing and into a volume enclosed by the housing.

34. The sealing arrangement according to claim 32, wherein the holding element is formed plate-shaped with oppositely arranged surfaces and at least one through opening for receiving the at least one connection terminal element.

35. The sealing arrangement according to claim 34, wherein an end face of the at least one connection terminal element is arranged flush with a surface of a side of the holding element oriented facing away from the housing.

36. The sealing arrangement according to claim 35, wherein the holding element, at a side oriented facing the housing, has a receptacle for the sealing element which is formed around an entire circumference of the at least one through opening and in a shape of a protrusion.

37. The sealing arrangement according to claim 36, wherein an elevation which is rectangular in cross-section is formed at a side of the receptacle oriented facing the housing.

38. The sealing arrangement according to claim 32, wherein the sealing element is formed in a ring-shaped manner around the longitudinal axis.

39. The sealing arrangement according to claim 38, wherein the sealing element has an incision formed around the entire circumference in a shape of a notch at a first end face which is oriented in an axial direction.

40. The sealing arrangement according to claim 38, wherein the sealing element is formed with at least two sealing lips which are oriented in an axial direction and which are arranged, at an end face thereof, running around the sealing element and concentrically to one another.

41. The sealing arrangement according to claim 40, wherein the at least two sealing lips are formed tapering in free end sections facing the axial direction.

42. The sealing arrangement according to claim 40, wherein a first sealing surface is formed at a lateral surface of a first inner one of the sealing lips pointing inwards in the radial direction and that a second sealing surface is formed at a lateral surface of a second outer one of the sealing lips pointing outwards in the radial direction.

43. The sealing arrangement according to claim 42, wherein the first sealing surface is arranged sealingly resting against the at least one connection terminal element and the second sealing surface is arranged sealingly resting against the housing.

44. The sealing arrangement according to claim 39, wherein the sealing element has a formation running around the entire circumference at a second end face oriented distally to the first end face in the axial direction.

45. The sealing arrangement according to claim 44, wherein the formation is formed in a shape of a crease which is rectangular in cross-section and whose shape and dimension corresponds to a receptacle of the holding element.

46. The sealing arrangement according to claim 32, wherein the at least one pressure element is formed substantially in a shape of a hollow cylinder with a tapering wall at a free end face facing the sealing element in an axial direction.

47. The sealing arrangement according to claim 39, wherein the at least one pressure element is arranged such that a wall protrudes into the incision formed in the sealing element.

48. The sealing arrangement according to claim 47, wherein the at least one pressure element is formed with sections with different inner diameters arranged along the longitudinal axis.

49. The sealing arrangement according to claim 48, wherein the at least one pressure element is formed with at least two sections with different inner diameters and a step-shaped transition at an inside.

50. The sealing arrangement according to claim 32, wherein the at least one connection terminal element is formed substantially in a shape of an annular cylinder with sections with different outer diameters arranged along the longitudinal axis.

51. The sealing arrangement according to claim 32, wherein the at least one connection terminal element is formed with an opening shaped as an annular cylinder for receiving the at least one connection element, starting from an end face oriented facing a direction of an outside of the housing and extending in the longitudinal direction of the at least one connection terminal element.

52. The sealing arrangement according to claim 50, wherein a first section of the at least one connection terminal element is arranged within a through opening formed in the holding element, wherein the first section of the at least one connection terminal element has an outer diameter which corresponds to an inner diameter of the through opening with a clearance.

53. The sealing arrangement according to claim 52, wherein the at least one connection terminal element has a second section joining the first section in the direction of the longitudinal axis and which is formed with an outer diameter larger than the first section.

54. The sealing arrangement according to claim 53, wherein the second section of the at least one connection terminal element is enclosed by the sealing element around the entire circumference at least in regions.

55. The sealing arrangement according to claim 54, wherein the second section of the at least one connection terminal element is formed with the outer diameter which corresponds to an inner diameter of the sealing element with a clearance.

56. The sealing arrangement according to claim 53, wherein the at least one connection terminal element has a third section joining the second section in the direction of the longitudinal axis and which is formed with an outer diameter smaller than the second section.

57. The sealing arrangement according to claim 56, wherein the third section and a region of the second section of the at least one connection terminal element arranged joining the third section are enclosed by the at least one pressure element around an entire circumference, wherein the at least one pressure element is arranged movably relative to the at least one connection terminal element.

58. The sealing arrangement according to claim 57, wherein a first section of the at least one pressure element is arranged in the region of the second section of the at least one connection terminal element and a second section of the at least one pressure element is arranged in a region of the third section of the at least one connection terminal element.

59. The sealing arrangement according to claim 56, wherein the at least one connection terminal element has a fourth section joining the third section in the direction of the longitudinal axis and which is formed with an outer diameter smaller than the third section.

60. The sealing arrangement according to claim 32, wherein the at least one connection element is formed as a pin-shaped plug connector in a shape of a cylinder.

61. The sealing arrangement according to claim 60, wherein the at least one connection element is formed in the shape of an annular cylinder with a constant outer diameter.

62. The sealing arrangement according to claim 60, wherein the at least one connection element, with a first end ahead, is arranged inserted in an opening formed as a blind hole, at an end face of the at least one connection terminal element oriented facing an outside of the housing.
